(19) United States
(12) Patent Application Publication
(10) Pub. No.: US 2010/0230722 A1
(43) Pub. Date: Sep. 16, 2010

(54) HIGH ELECTRON MOBILITY FIELD EFFECT TRANSISTOR (HEMT) DEVICE

(76) Inventors: Liann-Be CHANG, Kwei-Shan (TW); Hsien-Chin Chiu, Kwei-Shan (TW); Yun-Lin Lee, Kwei-Shan (TW); Chao-Wei Lin, Kwei-Shan (TW); Atanu Das, Kwei-Shan (TW)

Correspondence Address: Muncy, Geissler, Olds & Lowe, PLLC, 4000 Legato Road, Suite 310, FAIRFAX, VA, 22033, US

(21) Appl. No.: 12/613,168

(22) Filed: Nov. 5, 2009

(30) Foreign Application Priority Data
Mar. 10, 2009 (TW) 98107720

(51) Int. Cl. H01L 29/778

(52) U.S. Cl. 257/194; 257/E29.246

(57) ABSTRACT

A High Electron Mobility Transistor (HEMT) device, which is formed by connecting a plurality of low power flip-chip type High Electron Mobility Transistor (HEMT) elements in parallel, or connected them in parallel and in series in combination into a tree-shaped structure, and then connecting said structure to an input terminal and an output terminal. Distances between each of the flip-chip type HEMT elements, from each element to said input terminal, and from each element to said output terminal are designed to be equal, such that powers consumed by each of the flip-chip type HEMT elements are equal, currents flowing through are evenly distributed, and heat generated is liable to be dissipated. A spike leakage protection layer, such as zinc-oxide (ZnO) amorphous layer or poly-crystal layer, is further included, hereby further enhancing the efficiency of said flip-chip type HEMT element and prolonging its service life.

### BACKGROUND OF THE INVENTION

1. Field of the Invention

The present invention relates to a field effect transistor (FET) device, applicable in high frequency and high power microwave range, and in particular to a high electron mobility field effect transistor (HEMT) device, wherein, a plurality of low-power flip-chip type HEMT's are connected in parallel, or are connected to form a tree-shaped structure through a combination of series connections and parallel connections, so as to dissipate its heat generated, increase its efficiency, and prolong its service life span.

2. The Prior Arts

In recent years, the high electron mobility field effect transistor (HEMT) device is a hot topic and widely popular in the high frequency and high power microwave sphere. Since gallium nitride (GaN) material has the property of high chemical inertness, good heat stability, and strong bonding force, as such, it demonstrates superior heat resistant and corrosion resistant capability in an environment of high temperature and high corrosion. Electrically, though the electron mobility of gallium nitride (GaN) (˜1500 cm²/V-s) is not high as compared with that of gallium arsenide (GaAs) (˜7000 cm²/V-s) (about only one fifth), however, GaN has the following superior characteristics: 3.4 eV wide bandgap material characteristic, high breakdown voltage, high peak electron velocity, and high saturation velocity. Therefore, gallium nitride (GaN) is very much suitable for use in application of DC rectifier, power microwave amplifier, low noise microwave amplifier, and high temperature elements, etc.

Gallium nitride (GaN) material is capable of unique polarization effect, including spontaneous polarization and piezoelectric polarization. In the condition of without being doped any dopant, this polarization effect tends to form a two-dimensional-electron gases (2DEG) adjacent to an interface of an AlGaN/GaN heterogeneous structure through automatic induction. In a 2DEG, the electron concentration is related to the intensity of polarization. For an AlGaN/GaN heterogeneous structure, its 2DEG sheet electron concentration could reach 1×10¹³ cm⁻³, that is higher than the 2DEG electron concentration of conventional AlGaAs/GaAs heterogeneous structure by an order of magnitude. Therefore, a field-effect-transistor of AlGaN/GaN heterogeneous structure is able to output very large current.

In general, the operation temperature of electronic elements will greatly affect the reliability of a system. Thus, when the operation temperature exceeds a certain allowable limit, its physical properties tend to change, thus making the system to function and perform out of order. Therefore, the best and most direct way of increasing the stability of a system is to provide good heat dissipation. This phenomenon is particularly true for High Electron Mobility Transistor (HEMT). When HEMT's are applied in high frequency and high power microwave range, the heat it generates will increase along with the increase of frequency and power, as such, the need for heat dissipation is raised correspondingly, and presently, this problem has not been solved properly and satisfactorily.

### SUMMARY OF THE INVENTION

In view of the problems and drawbacks of the prior art, the present invention provide a high electron mobility transistor (HEMT) device, so as to overcome the problems of the prior art.

A major objective of the present invention is to provide a High Electron Mobility Transistor (HEMT) device, so as to overcome the shortcomings of the prior art. In this respect, the present invention is realized by means of flip-chips, wherein, the HEMT's are mounted onto a sub-mount, so that HEMT may have a better heat dissipation mechanism, thus increasing the efficiency of HEMT and prolong its service life span.

Therefore, in order to achieve the above-mentioned objective, the HEMT disclosed by the present invention comprises: an input terminal, an output terminal, and a plurality of flip-chip type HEMT elements. The plurality of flip-chip type HEMT elements can each connected to the input terminal and the output terminal in parallel, or they can be connected with each other in series and in parallel in combination, and then this combined structure is connected to the input terminal and output terminal to form a tree-shaped structure, such that the distances between each of the flip-chip type HEMT elements, from each element to the input terminal, and from each element to the output terminal are equal. Therefore, in this configuration, the power consumed by each of the flip-chip type HEMT elements are equal, current is evenly distributed, and heat generated is liable to be dissipated, hereby further enhancing the efficiency of flip-chip type HEMT element and prolonging its service life.

On the other hand, in the present invention, a sub-mount and at least a low power HEMT are provided to form each of the flip-chip type HEMT elements. The low power HEMT is bonded onto the sub-mount in a flip-chip way. Moreover, the sub-mount is made of material of high heat conductivity, as such, heat can be dissipated by means of high heat conductivity of the sub-mount, thus further enhancing the heat dissipation capability of the flip-chip type HEMT element, hereby enabling the flip-chip type HEMT element to be more efficient, its performance more stable, and having a longer service life span.

In addition, the present invention may include a spike leakage protection layer, such as zinc oxide (ZnO) amorphous layer or poly-crystal layer, such that the normal operations of elements thereon will be effectively protected by means of a mechanism that Schottky barrier at the boundary of a grain tends to breakdown at fast speed under a strong electric field.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of a High Electron Mobility Transistor (HEMT) device according to a first embodiment of the present invention;

FIG. 2 is a schematic diagram of High Electron Mobility Transistor (HEMT) element according to an embodiment of the present invention;

FIG. 3A is a schematic diagram of a low power High Electron Mobility Transistor (HEMT) according to an embodiment of the present invention;

FIG. 3B is a schematic diagram of a low power High Electron Mobility Transistor (HEMT) according to an embodiment of the present invention, that is bonded onto a sub-mount in a flip-chip way;

FIG. 4 is a schematic diagram of High Electron Mobility Transistor (HEMT) element according to another embodiment of the present invention;

FIG. 5 is a schematic diagram of a High Electron Mobility Transistor (HEMT) device according to a second embodiment of the present invention;

FIG. 6 is a schematic diagram of a High Electron Mobility Transistor (HEMT) element according to yet another embodiment of the present invention; and

FIG. 7 is a schematic diagram of a High Electron Mobility Transistor (HEMT) element according to still another embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

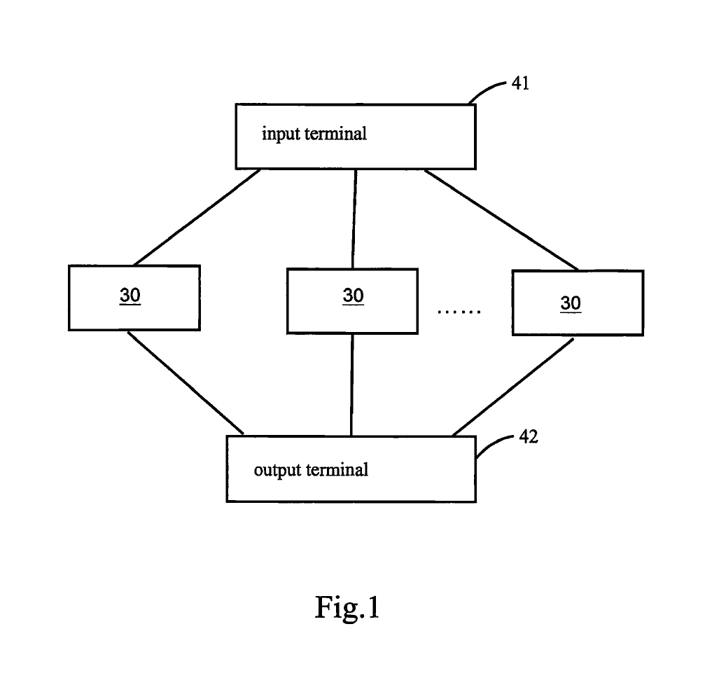

Refer to FIG. 1 for a schematic diagram of a High Electron Mobility Transistor (HEMT) device according to a first embodiment of the present invention. As shown in FIG. 1, a High Electron Mobility Transistor (HEMT) Device includes an input terminal 41, an output terminal 42, and a plurality of flip-chip type High Electron Mobility Transistor (HEMT) element 30; and each of a plurality of flip-chip type High Electron Mobility Transistor (HEMT) element 30 is connected to the input terminal 41 and output terminal 42 in parallel. In other words, each of the flip-chip type HEMT element 30 is connected to the input terminal 41 and output terminal 42 respectively. Meanwhile, the distance from each of the flip-chip type HEMT element 30 to the input terminal 41 is designed to be the same as the distance from each of the flip-chip type HEMT element 30 to the output terminal 42, such that the power they consume is identical, and the current distribution among them is even.

On the other hand, since the High Electron Mobility Transistor (HEMT) Device is formed by a plurality of flip-chip type HEMT elements 30, therefore, the low power High Electron Mobility Transistors (HEMT's) are utilized, such that in operation the heat generated can be dissipated quickly in cooperation with its flip-chip bonding way, hereby effectively raising the efficiency of heat dissipation.

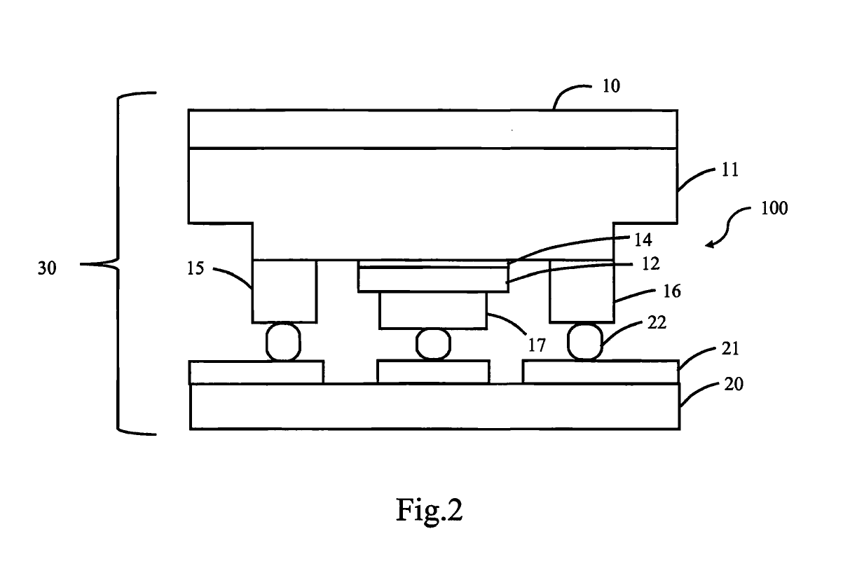

Refer to FIG. 2 for a schematic diagram of High Electron Mobility Transistor (HEMT) element according to an embodiment of the present invention. As shown in FIG. 2, High Electron Mobility Transistor (HEMT) Element 30 includes a sub-mount 20 and a low power High Electron Mobility Transistor (HEMT) 100, which is bonded onto sub-mount 20 in a flip-chip way. Besides, the sub-mount 20 is made of material of high heat conductivity, such that heat can be dissipated by means of high heat conductivity of sub-mount 20. Meanwhile, since low power HEMT's are utilized in order to dissipate heat, moreover, plus the design of high heat conductivity of sub-mount 20, thus the heat dissipation capability of HEMT element can be increased further, hereby enabling the HEMT element to be more efficient, its performance more stable, and having a longer service life span.

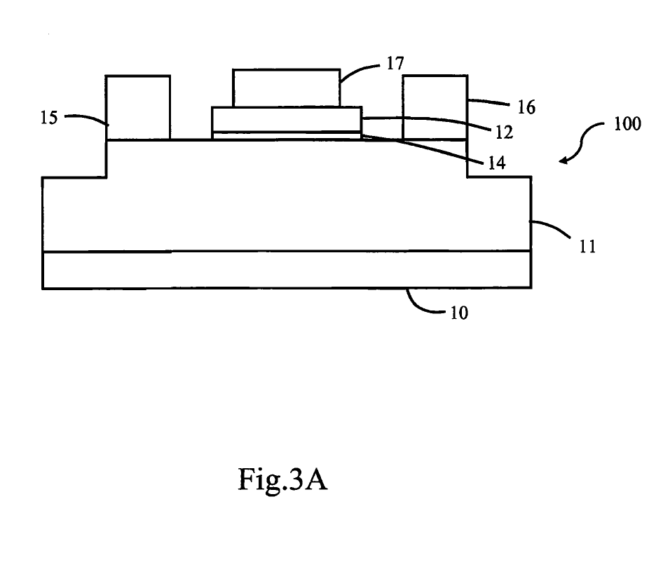

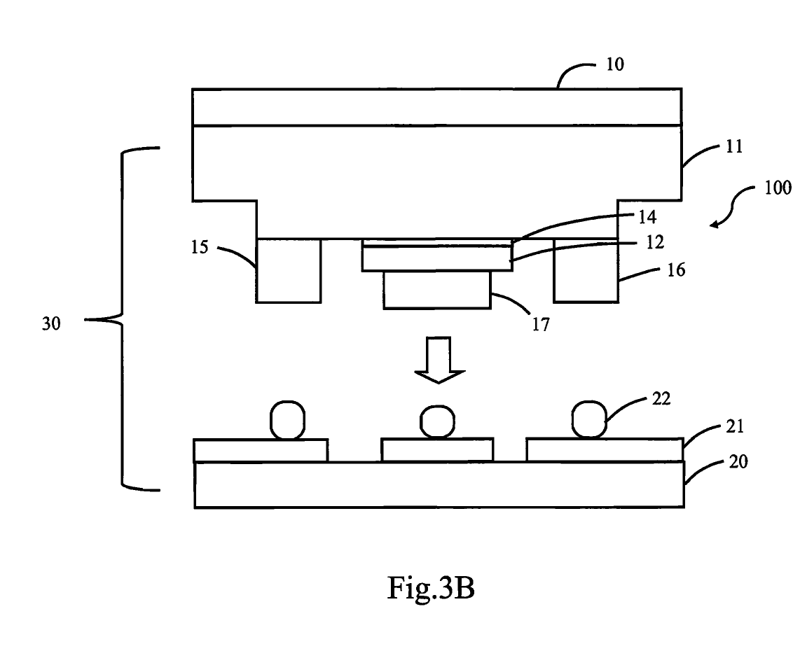

Refer to FIG. 3A for a schematic diagram of a low power High Electron Mobility Transistor (HEMT) according to an embodiment of the present invention. As shown in FIG. 3A, the low power High Electron Mobility Transistor (HEMT) 100 comprises: a substrate 10, a high resistance epitaxial layer 11, a barrier layer 12, a gate electrode contact metal 17, a source electrode contact metal 15, and a drain electrode contact metal 16. The substrate 10 is made of aluminum oxide (Al₂O₃) or silicon carbide (SiC), and depending on actual requirements, a buffer layer (not shown) can be grown thereon, a layer of undoped GaN can be grown on the buffer layer to serve as high resistance epitaxial layer 11, then a layer of AlGaN barrier layer 12 having largest energy gap is grown thereon. Subsequently, perform etch back on both sides of AlGaN barrier layer 12, thus forming a structure of protrusion at center, and indention at two sides. Then, performing evaporation of metals on the structure to form Schottky gate electrode contact metal 17, source electrode contact metal 15, and drain electrode contact metal 16; and gate electrode contact metal 17 and the barrier layer 12 together are used to form a two-dimensional-electron-gases (2DEG) layer 14.

Refer to FIG. 3B for a schematic diagram of a low power High Electron Mobility Transistor (HEMT) according to an embodiment of the present invention, that is bonded onto a sub-mount in a flip-chip way. As shown in FIG. 3B, the sub-mount 20 can be made of material of superior heat conductivity, such as aluminum nitride (AlN), zinc oxide (ZnO), and boron nitride (BN), and electrodes are produced on the sub-mount through utilizing a yellow light lithography process, thus forming at least three contact metal regions, and a conduction block 21 is grown on each of the three contact metal regions, subsequently, forming bump 22 or planting gold ball on each of the conduction blocks 21 to form the glue-on-and-contact points for bonding a low power High Electron Mobility Transistor (HEMT) 100 onto a sub-mount, in other words, as such providing a way for contacting and connecting gate electrode contact metal 17, source electrode contact metal 15, and drain electrode contact metal 16. Therefore, after bonding transistor on sub-mount in this flip-chip way, the heat dissipation efficiency and effectiveness of low power High Electron Mobility Transistor (HEMT) 100 can be enhanced by the high heat conductivity of sub-mount 20.

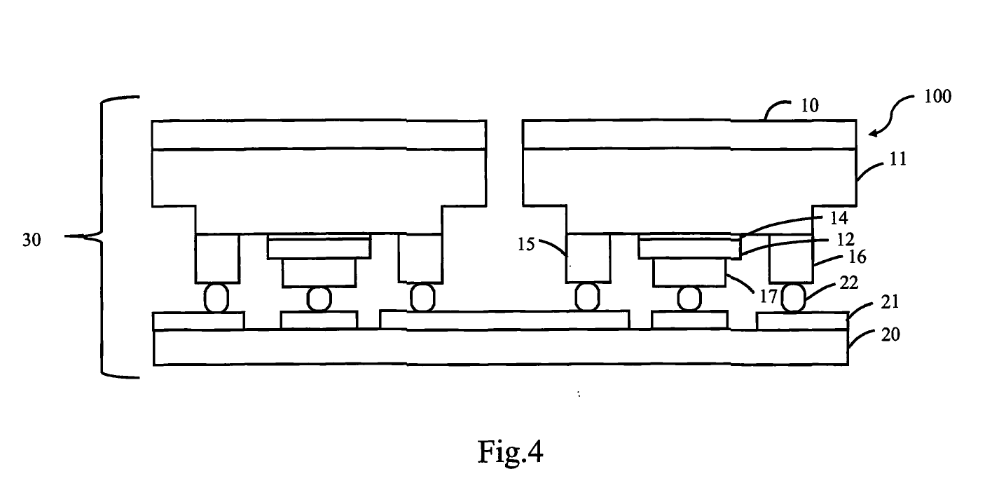

Moreover, refer to FIG. 4 for a schematic diagram of High Electron Mobility Transistor (HEMT) element according to another embodiment of the present invention. As shown in FIG. 4, two low power High Electron Mobility Transistors (HEMT's) 100 can be bonded onto a sub-mount 20 at the same time to form a High Electron Mobility Transistor (HEMT) element 30, thus enabling more effective heat dissipation and more even current distribution. Similarly, two dimensional array structure is arranged, so as to further raise its effectiveness.

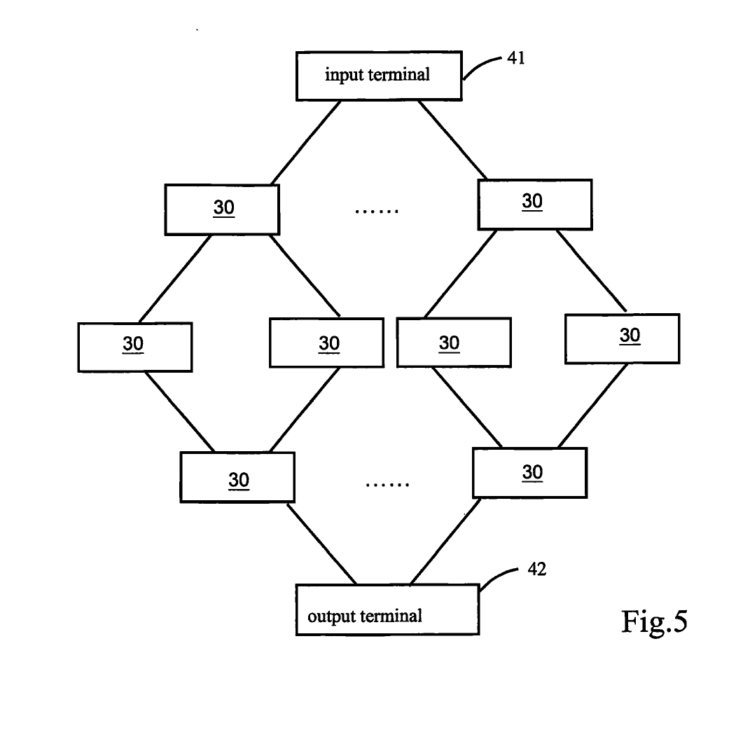

Refer to FIG. 5 for a schematic diagram of a High Electron Mobility Transistor (HEMT) device according to a second embodiment of the present invention. In addition to the parallel connection arrangement of High Electron Mobility Transistor (HEMT) element 30 of the first embodiment as shown in FIG. 1, a tree-shaped connection structure can be realized through combining the series-connection of flip-chip type HEMT elements and parallel-connection of flip-chip type HEMT elements together. As shown in FIG. 5, the tree-shaped structure is achieved through: first parallel-connecting two flip-chip type HEMT elements 30, and then each of the two flip-chip type HEMT elements 30 are series-connected with two flip-chip type HEMT elements 30, and then the structure thus formed is connected respectively to an input terminal 41 and an output terminal 42. Meanwhile, in addition to the requirement that each of the flip-chip type HEMT elements 30 must be of equal distance to the input terminal 41 and the output terminal 42, it is also required that equal distance must be maintained between each of the flip-chip type HEMT elements 30 as mentioned above. In general, in the arrangement of connection mentioned above, the number of flip-chip type HEMT elements utilized is preferably 2, 4, 8, etc. of n powers of 2. Since it is required that the wirings between flip-chip type HEMT elements must be of equal length, therefore isosceles triangle and equilateral triangle are the most convenient and appropriate design pattern, hereby achieving isotropic amplification of the same phase and same power.

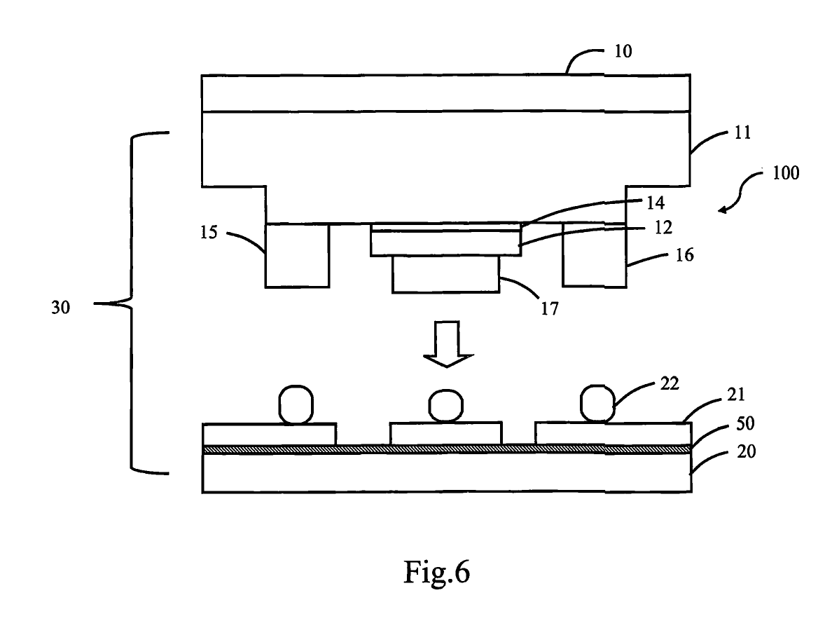

Refer to FIG. 6 for a schematic diagram of a High Electron Mobility Transistor (HEMT) element according to yet another embodiment of the present invention. In this embodiment, the High Electron Mobility Transistor (HEMT) element 30 further includes a spike leakage protection layer 50, such as a zinc oxide (ZnO) amorphous layer or poly-crystal layer, disposed between a sub-mount 20 and a conduction block 21, such that the normal operations of elements thereon can be effectively protected by means of a mechanism that Schottky barrier at the boundary of a grain tends to breakdown at fast speed under a strong electric field, thus raising the efficiency of the elements and prolonging their service life span.

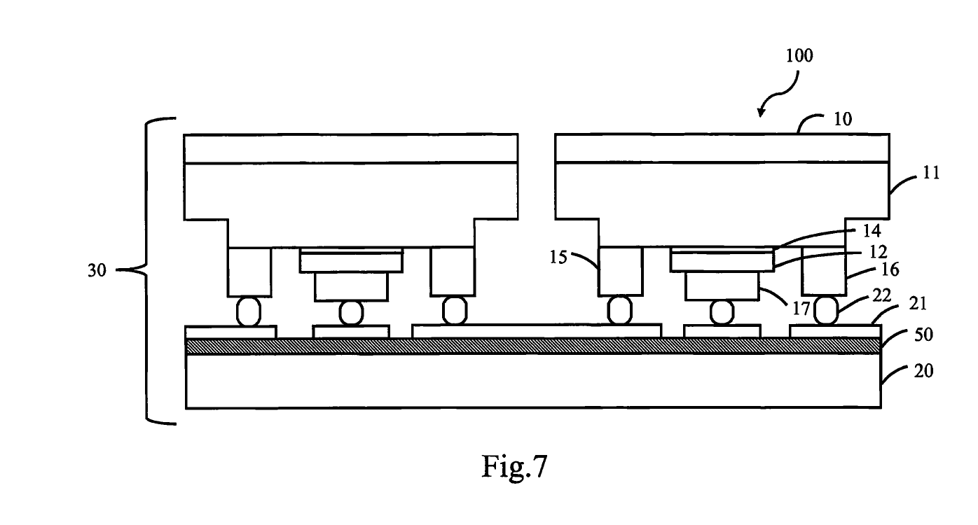

Refer to FIG. 7 for a schematic diagram of a High Electron Mobility Transistor (HEMT) element according to still another embodiment of the present invention. Similar to the embodiment as shown in FIG. 4, a High Electron Mobility Transistor (HEMT) element 30 having a spike leakage protection layer 50 can be realized by bonding two low power High Electron Mobility Transistors (HEMT's) 100 on a sub-mount 20 at the same time, thus enabling more effective heat dissipation and more even current distribution. Similarly, a two dimensional array structure such as a “ [symbol] ” shape can be arranged, so as to further raise its effectiveness.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A High Electron Mobility Transistor (HEMT) device, comprising:
an input terminal and an output terminal; and
a plurality of flip-chip type HEMT elements connected in parallel respectively to said input terminal and said output terminal, such that distances from each said flip-chip type HEMT element to said input terminal, and to said output terminal are equal, wherein, each of said flip-chip type HEMT elements includes:
a sub-mount, made of high thermal conductivity material; and
at least a low power High Electron Mobility Transistor (HEMT), bonded onto said sub-mount in a flip-chip way, such that heat is dissipated through said sub-mount.

2. The High Electron Mobility Transistor (HEMT) device of claim 1, wherein
said high thermal conductivity material is selected from the group consisting of aluminum nitride (AlN), zinc oxide (ZnO), and boron nitride (BN).

3. The High Electron Mobility Transistor (HEMT) device of claim 1, wherein
said low power High Electron Mobility Transistor (HEMT) comprises:
a substrate;
a high resistance epitaxial layer, disposed on said substrate;
a barrier layer, disposed on said high resistance epitaxial layer; and
a gate electrode contact metal, a source electrode contact metal, and a drain electrode contact metal, formed on said high resistance epitaxial layer and said barrier layer.

4. The High Electron Mobility Transistor (HEMT) device of claim 3, wherein
said substrate is made of aluminum oxide (Al₂O₃) or silicon carbide (SiC).

5. The High Electron Mobility Transistor (HEMT) device of claim 3, wherein
a buffer layer is provided between said substrate and said high resistance epitaxial layer.

6. The High Electron Mobility Transistor (HEMT) device of claim 3, wherein
said high resistance epitaxial layer is formed by un-doped GaN.

7. The High Electron Mobility Transistor (HEMT) device of claim 3, wherein
said barrier is made of a highest energy gap AlGaN.

8. The High Electron Mobility Transistor (HEMT) device of claim 3, wherein
said barrier layer is etched back to form a structure of center protrusion and indentation at two sides, and said gate electrode contact metal, said source electrode contact metal, and said drain electrode contact metal are formed on said center protrusion.

9. The High Electron Mobility Transistor (HEMT) device of claim 8, wherein
a two-dimensional-electron-gases (2DEG) layer is formed below said gate electrode contact metal and said barrier layer.

10. The High Electron Mobility Transistor (HEMT) device of claim 3, wherein
at least three contact metal regions are formed on said sub-mount through a yellow light lithography process, and a conduction block is grown on each of said three contact metal regions, and is connected to said gate electrode contact metal, said source electrode contact metal, and said drain electrode contact metal respectively.

11. The High Electron Mobility Transistor (HEMT) device of claim 10, wherein
said conduction block is a bump or a gold ball.

12. The High Electron Mobility Transistor (HEMT) device of claim 1, wherein
said flip-chip type High Electron Mobility Transistor (HEMT) element further includes a spike leakage protection layer, located between said low power High Electron Mobility Transistor (HEMT) and said sub-mount.

13. The High Electron Mobility Transistor (HEMT) device of claim 12, wherein
said spike leakage protection layer is formed by Zinc-Oxide (ZnO) amorphous layer or poly-crystal layer.

14. A High Electron Mobility Transistor (HEMT) device, comprising:
an input terminal and an output terminal; and
a plurality of flip-chip type HEMT elements, connected with each other to form a tree-shaped structure, and then are connected to said input terminal and said output terminal, such that distances between each of said flip-chip type HEMT elements, to said input terminal, and to said output terminal are equal, wherein, each of said flip-chip type HEMT elements includes:
a sub-mount, made of high thermal conductivity material; and
at least a low power High Electron Mobility Transistor (HEMT), bonded on said sub-mount in a flip-chip way, such that heat is dissipated through high heat conductivity of said sub-mount.

15. The High Electron Mobility Transistor (HEMT) device of claim 14, wherein
said high thermal conductivity material is selected from the group consisting of aluminum nitride (AlN), zinc oxide (ZnO), and boron nitride (BN).

16. The High Electron Mobility Transistor (HEMT) device of claim 14, wherein
said low power High Electron Mobility Transistor (HEMT) comprises:
a substrate;
a high resistance epitaxial layer, disposed on said substrate;
a barrier layer, disposed on said high resistance epitaxial layer; and
a gate electrode contact metal, a source electrode contact metal, and a drain electrode contact metal are formed on said high resistance epitaxial layer and said barrier layer.

17. The High Electron Mobility Transistor (HEMT) device of claim 16, wherein
said substrate is made of aluminum oxide (Al₂O₃) or silicon carbide (SiC).

18. The High Electron Mobility Transistor (HEMT) device of claim 16, wherein
a buffer layer is provided between said substrate and said high resistance epitaxial layer.

19. The High Electron Mobility Transistor (HEMT) device of claim 16, wherein
said high resistance epitaxial layer is formed by un-doped GaN.

20. The High Electron Mobility Transistor (HEMT) device of claim 16, wherein
said barrier is made of a highest energy gap AlGaN.

21. The High Electron Mobility Transistor (HEMT) device of claim 16, wherein
said barrier layer is etched back to form a structure of center protrusion and indentation at two sides, and said gate electrode contact metal, said source electrode contact metal, and said drain electrode contact metal are formed on said center protrusion.

22. The High Electron Mobility Transistor (HEMT) device of claim 21, wherein
a two-dimensional-electron-gases (2DEG) layer is formed below said gate electrode contact metal and said barrier layer.

23. The High Electron Mobility Transistor (HEMT) device of claim 16, wherein
at least three contact metal regions are formed on said sub-mount through a yellow light lithography process, and a conduction block is grown on each of said three contact metal regions, and is connected to said gate electrode contact metal, said source electrode contact metal, and said drain electrode contact metal respectively.

24. The High Electron Mobility Transistor (HEMT) device of claim 23, wherein
said conduction block is a bump or a gold ball.

25. The High Electron Mobility Transistor (HEMT) device of claim 14, wherein
said flip-chip type High Electron Mobility Transistor (HEMT) element further includes a spike leakage protection layer, located between said low power High Electron Mobility Transistor (HEMT) and said sub-mount.

26. The High Electron Mobility Transistor (HEMT) device of claim 25, wherein
said spike leakage protection layer is formed by zinc-oxide (ZnO) amorphous layer or poly-crystal layer.
